(19) United States
(12) Patent Application Publication
(10) Pub. No.: US 2026/0093860 A1
(43) Pub. Date: Apr. 2, 2026

(54) SYSTEMS AND METHODS FOR DETERMINING ATTRIBUTES OF SPACES

(71) Applicant: CoStar Realty Information, Inc., Arlington, VA (US)

(72) Inventors: David Alan Gausebeck, Sunnyvale, CA (US); Gunnar Hovden, Sunnyvale, CA (US); Arindam Ashim Bose, Sunnyvale, CA (US); Olaf Brandt, Sunnyvale, CA (US); Haakon Erichsen, Sunnyvale, CA (US)

(73) Assignee: CoStar Realty Information, Inc., Arlington, VA (US)

(21) Appl. No.: 19/345,971

(22) Filed: Sep. 30, 2025

Related U.S. Application Data
(60) Provisional application No. 63/701,203, filed on Sep. 30, 2024.

(51) Int. Cl. G06F 30/13; G06T 15/06

(52) U.S. Cl. CPC G06F 30/13; G06T 15/06; G06T 2210/04

(57) ABSTRACT

An example method includes receiving data for a space. The space may include one or more floor portions and one or more ceiling portions. The data may include depth data for the space or images of the space. One or more geometries for the space may be generated based on the data. Floor data for the one or more floor portions and ceiling data for the one or more ceiling portions may be determined based on the one or more geometries. One or more ceiling heights for the one or more ceiling portions may be determined based on the floor data and the ceiling data. The one or more ceiling heights may be provided for display.

### CROSS-REFERENCE TO RELATED APPLICATION

This application claims priority to and seeks the benefit of U.S. Provisional Ser. No. 63/701,203 , filed on Sep. 30, 2024, and entitled “SYSTEMS AND METHODS FOR CEILING HEIGHT DETERMINATION USING A 3D MODEL,” which is incorporated in its entirety herein by reference.

### TECHNICAL FIELD

The present disclosure relates in general to determining attributes of spaces, and in particular to determining attributes of ceilings, such as ceiling heights and ceiling shapes, of spaces.

### BACKGROUND

Ceiling height and ceiling shape are important room characteristics that people often need information about to make informed decisions about a space. Today, too many rooms do not include ceiling height information. This makes for an inconsistent experience in viewing 3D models of spaces and leads to an incomplete understanding of spaces. Furthermore, ceiling height may be an important factor in determining whether a space meets certain regulatory standards.

### SUMMARY

In some aspects, the techniques described herein relate to one or more non-transitory computer-readable media including executable instructions, the executable instructions being executable by one or more processors to perform a method, the method including: receiving data for a space, the space including one or more floor portions and one or more ceiling portions, the data including depth data for the space or images of the space; generating, based on the data, one or more geometries for the space; determining, based on the one or more geometries, floor data for the one or more floor portions and ceiling data for the one or more ceiling portions; determining, based on the floor data and the ceiling data, one or more ceiling heights for the one or more ceiling portions; and providing the one or more ceiling heights for display.

In some aspects, the techniques described herein relate to one or more non-transitory computer-readable media, the method further including: determining, based on the ceiling data, one or more ceiling shapes for the one or more ceiling portions; and providing the one or more ceiling shapes for display.

In some aspects, the techniques described herein relate to one or more non-transitory computer-readable media, the method further including: displaying one or more 3D representations of the space, the one or more 3D representations including the one or more ceiling heights; receiving one or more inputs to modify the one or more 3D representations; updating, based on the one or more inputs, the one or more ceiling heights to generate one or more updated ceiling heights; and displaying the one or more 3D representations, the one or more 3D representations including the one or more updated ceiling heights.

In some aspects, the techniques described herein relate to one or more non-transitory computer-readable media wherein the one or more ceiling heights include one or more minimum ceiling heights, one or more maximum ceiling heights, or one or more median ceiling heights.

In some aspects, the techniques described herein relate to one or more non-transitory computer-readable media, the method further including: generating a floor plan for the space, the floor plan including the one or more ceiling heights; and providing the floor plan for display.

In some aspects, the techniques described herein relate to one or more non-transitory computer-readable media wherein the one or more geometries include one or more 3D meshes, the one or more 3D meshes including one or more first 3D portions representing the one or more floor portions or first items proximate to the one or more floor portions and one or more second 3D portions representing the one or more ceiling portions or second items proximate to the one or more ceiling portions, and wherein determining, based on the one or more geometries, the floor data and the ceiling data includes: casting rays to impact the one or more first 3D portions; casting rays to impact the one or more second 3D portions; determining, based on casting rays, one or more floor elevations and one or more ceiling elevations; and determining, based on the one or more floor elevations and the one or more ceiling elevations, the floor data and the ceiling data.

In some aspects, the techniques described herein relate to one or more non-transitory computer-readable media wherein casting rays to impact the one or more first 3D portions includes casting rays to impact the one or more first 3D portions from first positions that are outside the one or more 3D meshes and casting rays to impact the one or more second 3D portions includes casting rays to impact the one or more second 3D portions from second positions that are outside the one or more 3D meshes.

In some aspects, the techniques described herein relate to one or more non-transitory computer-readable media wherein casting rays to impact the one or more first 3D portions includes casting rays to impact the one or more first 3D portions from first positions that are within the one or more 3D meshes and casting rays to impact the one or more second 3D portions includes casting rays to impact the one or more second 3D portions from second positions that are within the one or more 3D meshes.

In some aspects, the techniques described herein relate to one or more non-transitory computer-readable media wherein determining, based on casting rays, the one or more floor elevations includes: determining multiple initial floor elevations; determining multiple floor tilts; weighting, based on the multiple floor tilts, the multiple initial floor elevations to generate multiple weighted initial floor elevations; and determining, based on the multiple weighted initial floor elevations, the one or more floor elevations.

In some aspects, the techniques described herein relate to one or more non-transitory computer-readable media wherein determining, based on casting rays, the one or more ceiling elevations includes: determining multiple initial ceiling elevations; determining multiple ceiling tilts and multiple ceiling yaws; and determining, based on the multiple ceiling tilts and the multiple ceiling yaws, the one or more ceiling elevations.

In some aspects, the techniques described herein relate to one or more non-transitory computer-readable media wherein the one or more ceiling heights include a maximum ceiling height or a minimum ceiling height, and the method further includes: determining a location for the maximum ceiling height or the minimum ceiling height; and providing the location for display.

In some aspects, the techniques described herein relate to one or more non-transitory computer-readable media wherein determining the location for the maximum ceiling height or the minimum ceiling height includes: determining, based on the one or more geometries, one or more ceiling planes; and determining, based on the one or more ceiling planes, the location for the maximum ceiling height or the minimum ceiling height.

In some aspects, the techniques described herein relate to a method including: receiving data for a space, the space including one or more floor portions and one or more ceiling portions, the data including depth data for the space or images of the space; generating, based on the data, one or more geometries for the space; determining, based on the one or more geometries, floor data for the one or more floor portions and ceiling data for the one or more ceiling portions; determining, based on the floor data and the ceiling data, one or more ceiling heights for the one or more ceiling portions; and providing the one or more ceiling heights for display.

In some aspects, the techniques described herein relate to a method, further including: determining, based on the ceiling data, one or more ceiling shapes for the one or more ceiling portions; and providing the one or more ceiling shapes for display.

In some aspects, the techniques described herein relate to a method, further including: displaying one or more 3D representations of the space, the one or more 3D representations including the one or more ceiling heights; receiving one or more inputs to modify the one or more 3D representations; updating, based on the one or more inputs, the one or more ceiling heights to generate one or more updated ceiling heights; and displaying the one or more 3D representations, including the one or more updated ceiling heights.

In some aspects, the techniques described herein relate to a method wherein the one or more ceiling heights include one or more minimum ceiling heights, one or more maximum ceiling heights, or one or more median ceiling heights.

In some aspects, the techniques described herein relate to a method, further including: generating a floor plan for the space, the floor plan including the one or more ceiling heights; and providing the floor plan for display.

In some aspects, the techniques described herein relate to a method wherein the one or more geometries include one or more 3D meshes, the one or more 3D meshes including one or more first 3D portions representing the one or more floor portions or first items proximate to the one or more floor portions and one or more second 3D portions representing the one or more ceiling portions or second items proximate to the one or more ceiling portions, and wherein determining, based on the one or more geometries, the floor data and the ceiling data includes: casting rays to impact the one or more first 3D portions; casting rays to impact the one or more second 3D portions; determining, based on casting rays, one or more floor elevations and one or more ceiling elevations; and determining, based on the one or more floor elevations and the one or more ceiling elevations, the floor data and the ceiling data.

In some aspects, the techniques described herein relate to a method wherein casting rays to impact the one or more first 3D portions includes casting rays to impact the one or more first 3D portions from first positions that are outside the one or more 3D meshes and casting rays to impact the one or more second 3D portions includes casting rays to impact the one or more second 3D portions from second positions that are outside the one or more 3D meshes.

In some aspects, the techniques described herein relate to a method wherein casting rays to impact the one or more first 3D portions includes casting rays to impact the one or more first 3D portions from first positions that are within the one or more 3D meshes and casting rays to impact the one or more second 3D portions includes casting rays to impact the one or more second 3D portions from second positions that are within the one or more 3D meshes.

In some aspects, the techniques described herein relate to a method wherein determining, based on casting rays, the one or more floor elevations includes: determining multiple initial floor elevations; determining multiple floor tilts; weighting, based on the multiple floor tilts, the multiple initial floor elevations to generate multiple weighted initial floor elevations; and determining, based on the multiple weighted initial floor elevations, the one or more floor elevations.

In some aspects, the techniques described herein relate to a method wherein determining, based on casting rays, the one or more ceiling elevations includes: determining multiple initial ceiling elevations; determining multiple ceiling tilts and multiple ceiling yaws; and determining, based on the multiple ceiling tilts and the multiple ceiling yaws, the one or more ceiling elevations.

In some aspects, the techniques described herein relate to a method wherein the one or more ceiling heights include a maximum ceiling height or a minimum ceiling height, and further including: determining a location for the maximum ceiling height or the minimum ceiling height; and providing the location for display.

In some aspects, the techniques described herein relate to a method wherein determining the location for the maximum ceiling height or the minimum ceiling height includes: determining, based on the one or more geometries, one or more ceiling planes; and determining, based on the one or more ceiling planes, the location for the maximum ceiling height or the minimum ceiling height.

In some aspects, the techniques described herein relate to a system including at least one processor and at least one memory including executable instructions that when executed by the at least one processor cause the system to: receive data for a space, the space including one or more floor portions and one or more ceiling portions, the data including depth data for the space or images of the space; generate, based on the data, one or more geometries for the space; determine, based on the one or more geometries, floor data for the one or more floor portions and ceiling data for the one or more ceiling portions; determine, based on the floor data and the ceiling data, one or more ceiling heights for the one or more ceiling portions; and provide the one or more ceiling heights for display.

### BRIEF DESCRIPTION OF THE DRAWINGS

FIG. 1 depicts an example environment in which an attribute determination system may operate in some embodiments.

FIG. 2 is a block diagram depicting components of the attribute determination system according to some embodiments.

FIG. 3 is a flow diagram depicting a method for determining attributes of a space in some embodiments.

FIG. 4 is a diagram depicting intersections of rays and portions of one or more 3D meshes according to some embodiments.

FIG. 5 is a diagram depicting intersections of rays and ceiling portions of one or more 3D meshes according to some embodiments.

FIG. 6 is another diagram depicting intersections of rays and ceiling portions of one or more 3D meshes according to some embodiments.

FIG. 7A to 7G depict example approaches for determining a position for displaying a ceiling height in some embodiments.

FIGS. 8A to 8E depict a user interface displaying a 3D representation of a space according to some embodiments.

FIG. 9 is a block diagram of an example digital device according to various embodiments.

Throughout the drawings, like reference numerals will be understood to refer to like parts, components, and structures.

### DETAILED DESCRIPTION

Described herein is an attribute determination system that may determine attributes of spaces, such as ceiling heights and ceiling shapes. A space may be a building, such as a residential, commercial, or industrial building, or another type of structure. The attribute determination system may receive data for the space, such as images, videos, or three-dimensional (3D) data for the space. The attribute determination system may use the data to generate one or more geometries for the space, such as one or more 3D meshes. The attribute determination system may use the one or more geometries to determine floor elevations for the floors and ceiling elevations for the ceilings of rooms of the space. The attribute determination system may determine ceiling heights based on the floor elevations and the ceiling elevations. Ceiling heights may be referred to herein as room heights. The attribute determination system may also utilize ceiling elevations or ceiling heights to determine ceiling shapes.

The ceiling heights or the ceiling shapes may be utilized in various ways. For example, the ceiling heights or the ceiling shapes may be provided with 3D representations of the space and displayed with the 3D representations. A 3D representation of a space may be referred to herein as a 3D model or as a digital twin of the space. Viewers of the 3D representations may thus be informed of the ceiling heights and ceiling shapes of rooms of the space. In the residential property context, such information may help viewers make informed decisions regarding potential purchases of residential property. Further, the ceiling height and ceiling shape information may be shared and utilized via application programming interfaces (APIs) or other data integrations.

Another use of the ceiling heights may be for purposes of determining livable areas in residential properties. Various jurisdictions may have requirements related to ceiling height that a room or area in a residential home must meet in order to be considered livable area under the requirements. The ceiling height may be utilized to determine if the room or the area meets the requirements to be considered livable area.

The ceiling height may also be utilized to determine a volume of a room or area of a space. The volume may then be utilized to determine if a heating, ventilation, and air conditioning (HVAC) system is sufficient to heat or cool the room or area. For example, volume of a room or an area of a space may be compared to HVAC system capabilities to determine whether the HVAC system is capable or incapable of adequately cooling or heating the room or the area of the space.

The discussion herein may address determining ceiling heights for a room, but it will be appreciated that many of the embodiments described herein can be directed to any space or part of a space. For example, the space may be user-defined or may have physical limitations that assist in defining the space before ceiling height is determined for that defined space.

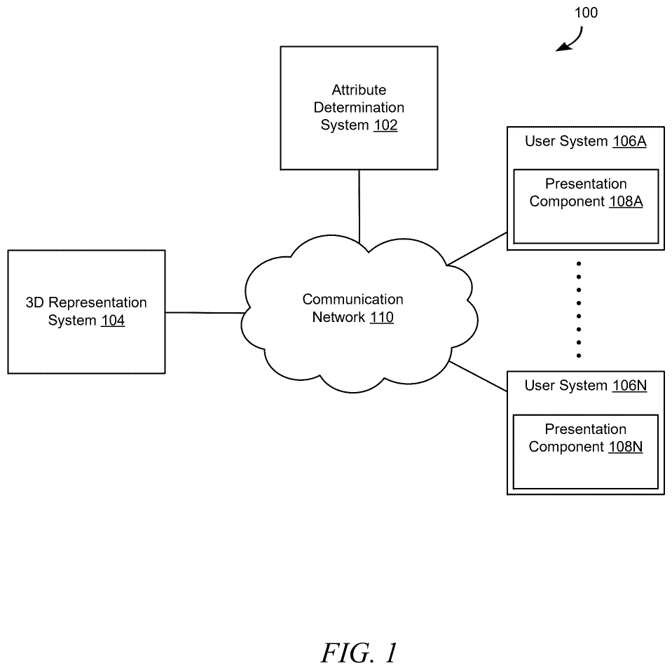

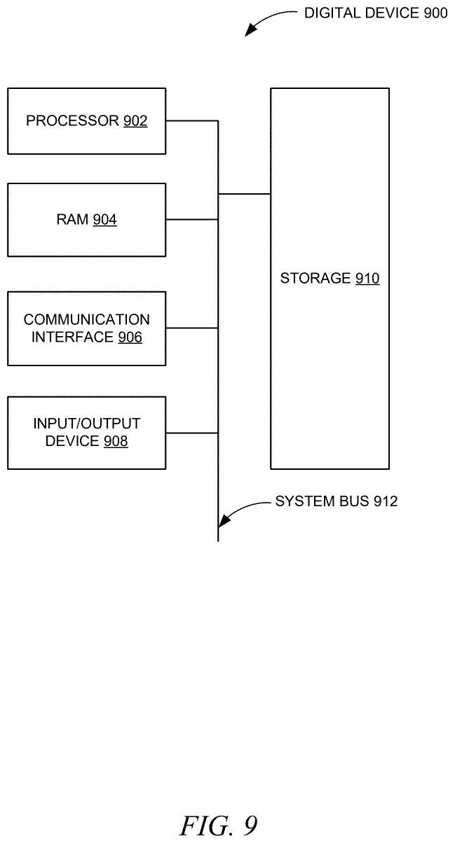

FIG. 1 depicts an example environment 100 in which an attribute determination system may operate according to some embodiments. The environment 100 includes an attribute determination system 102, a 3D representation system 104, multiple user systems 106A through 106N (which may be referred to as a user system 106 or as user systems 106), and a communication network 110. Each of the attribute determination system 102, the 3D representation system 104, and the user systems 106 may be or include any number of digital devices. A digital device is any device with at least one processor and memory. Digital devices are discussed further herein, for example, with reference to FIG. 9.

The attribute determination system 102 may receive data, such as 3D data and 2D data, for spaces. Examples of 3D data are 3D meshes or other 3D surface representations, point clouds or other 3D clouds, such as Gaussian splats, radiance fields or other neural representations, and voxel or other volumetric or solid representations, such as constructive solid geometry (CSG) representations. The 3D data may include depth data captured by 3D cameras such as the Matterport Pro 3 camera. Additionally or alternatively, the 3D data may include depth data derived from images or video captured by 360-degree cameras such as the Ricoh Theta series of 360-degree cameras, mobile phones or tablets such as iOS operating system phones or tablets and Android operating system phones or tablets, or aerial drones. As described in more detail herein, the attribute determination system 102 may utilize the data to determine attributes for spaces, such as heights or shapes of ceilings in the spaces.

The 3D representation system 104 may store 3D representations and provide 3D representations to various systems, such as to the user systems 106, so that the systems may display the 3D representations. In some embodiments, the 3D representation system 104 may allow users to edit or otherwise customize 3D representations. One example of a component that may allow users to edit 3D representations is Matterport Workshop.

The user systems 106 may each be or include a system that includes a presentation component 108 (shown individually as presentation components 108A through 108N) that is configured to display 3D representations (for example, using one or more display devices) and allow for navigation and exploration of 3D representations. Examples of user systems 106 are mobile phones or tablets, desktop or laptop computing devices, virtual or augmented reality devices, and televisions. One example of the presentation component 108 is the Matterport 3D Showcase interactive web player that may be included in a web browser that may execute on a desktop or laptop computing device or on a mobile phone or tablet.

The attribute determination system 102, the 3D representation system 104, and the presentation component 108 (individually or in a group) may be referred to as a system. Accordingly, a system may be interpreted as comprising any of the attribute determination system 102, the 3D representation system 104, or the presentation component 108. Similarly, functionality described as performed by a system may be performed by any of the attribute determination system 102, the 3D representation system 104, or the presentation component 108.

In some embodiments, the communication network 110 may represent one or more computer networks (for example, local area networks (LANs), wide area networks (WANs), or the like). The communication network 110 may provide or facilitate communication between any of the attribute determination system 102, the 3D representation system 104, and the user systems 106. In some implementations, the communication network 110 comprises computer devices, routers, cables, or other network topologies. In some embodiments, the communication network 110 may be wired or wireless. In various embodiments, the communication network 110 may comprise the Internet, one or more networks that may be public, private, IP-based, non-IP based, and so forth.

Although the environment 100 depicted in FIG. 1 has a specific configuration and the corresponding description relates specific functionality and features, it is to be understood that variations of the configuration depicted, or the functionality and features described, are possible. For example, there may be multiple attribute determination systems 102. As another example, the 3D representation system 104 may provide 3D representations to other systems not in the environment 100 (for example, computing systems of real-estate listing websites or other property information websites) for display. As another example, functionality described as being provided by the attribute determination system102 may be provided by the 3D representation system 104 or the user systems 106. Accordingly, the disclosure is not limited to the description herein.

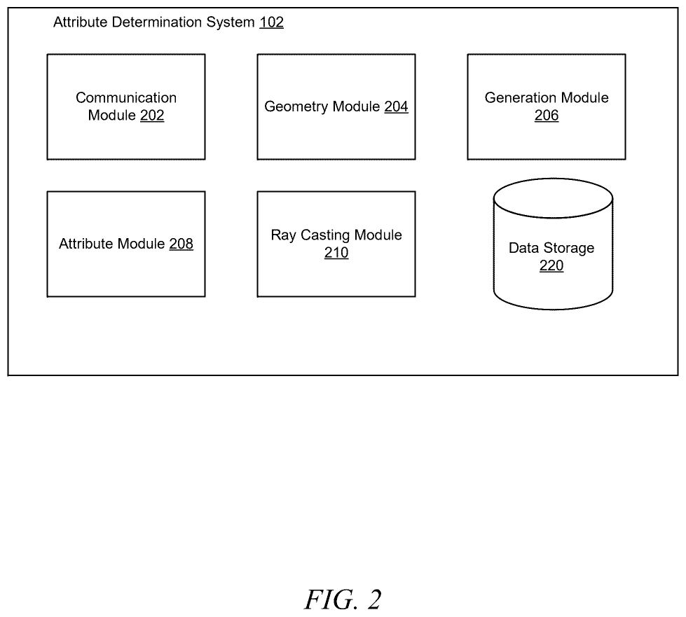

FIG. 2 is a block diagram depicting components of the attribute determination system 102 according to some embodiments. The attribute determination system 102 may include a communication module 202, a geometry module 204, a generation module 206, an attribute module 208, a ray casting module 210, and a data storage 220.

The communication module 202 may send requests or data between the attribute determination system 102 and any of the 3D representation system 104 and the user systems 106. For example, the communication module 202 may receive data for a space, such as images of the space or depth data for the space.

The geometry module 204 may generate geometries for spaces. For example, the geometry module 204 may generate, based on the data received for a space, one or more geometries for the space. For example, the geometry module 204 may generate one or more 3D meshes for the space.

The generation module 206 may generate 3D representations or content included in 3D representations, such as 2D floor plans or 3D floor plans. For example, the generation module 206 may generate a 3D floor plan that includes ceiling heights or other measurements (for example, lengths or widths) of rooms or other areas of a space. As another example, the generation module 206 may generate a 2D floor plan that includes the measurements (for example, lengths or widths) of rooms or other areas of a space as well as ceiling heights.

The attribute module 208 may determine attributes of portions of spaces. For example, the attribute module 208 may determine attributes such as elevations for floor or ceiling portions of spaces, as well as ceiling heights for the ceiling portions. The attribute module 208 may also determine ceiling shapes.

The ray casting module 210 may cast rays to impact portions of one or more geometries. For example, the ray casting module 210 may cast rays to determine initial floor elevations and floor tilts that may be used by the attribute module 208 to determine a floor elevation. Similarly, the ray casting module 210 may cast rays to determine initial ceiling elevations, ceiling tilts, and ceiling yaws that may be used by the attribute module 208 to determine a ceiling elevation.

The data storage 220 may include data stored, accessed, or modified by any of the modules of the attribute determination system 102. The data storage 220 may include any number of data storage structures such as tables, databases, lists, or the like. The data storage 220 may include data that is stored in memory (for example, random access memory (RAM)), on disk or on solid-state devices, or some combination of in-memory and on-disk or on solid-state devices.

A module of the attribute determination system 102 may be hardware, software, firmware, or any combination. For example, each module may include functions performed by dedicated hardware (for example, an Application-Specific Integrated Circuit (ASIC), a Field Programmable Gate Array (FPGA), or the like), software, instructions maintained in random access memory (RAM) or read-only memory (ROM), or any combination. Software may be executed by one or more processors. Although a limited number of modules are depicted in FIG. 2, there may be any number of modules. Further, individual modules may perform any number of functions, including functions of multiple modules as described herein.

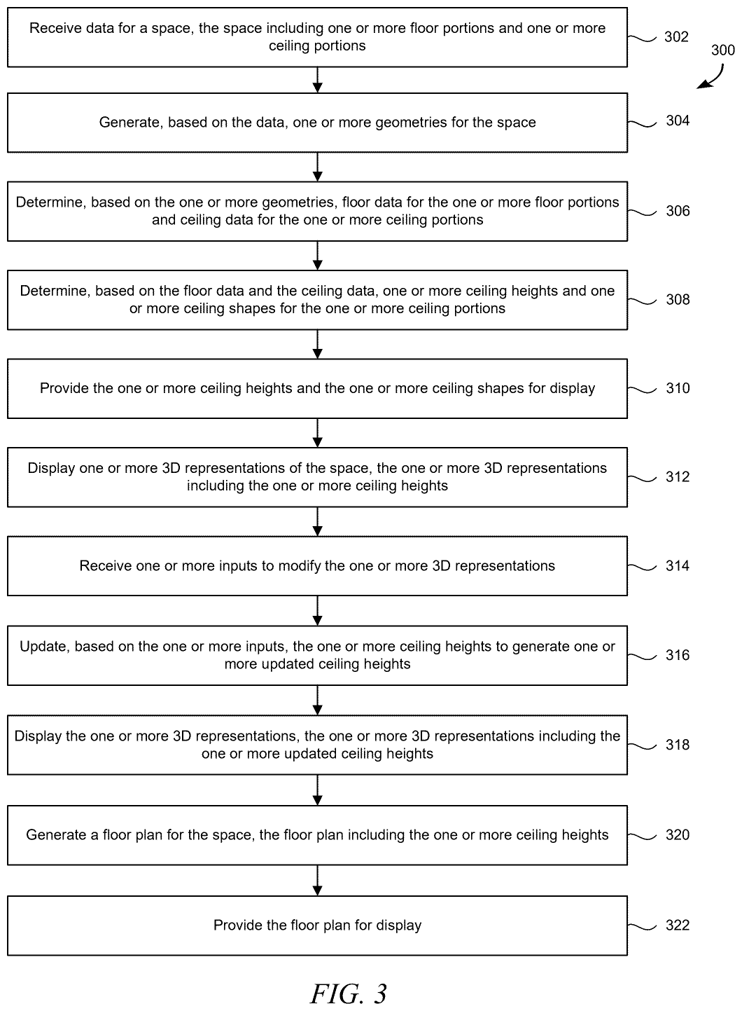

FIG. 3 is a flow diagram depicting a method 300 for determining attributes of a space in some embodiments. The attribute determination system 102 (for example, various modules of the attribute determination system 102) may perform the method 300. The method 300 is described using the example of spaces that are or include buildings or other structures. However, it will be understood that aspects of the method 300 may be applicable spaces that are not and do not include buildings. For example, aspects of the method 300 may be used to determine a height of a subterranean cave.

The method 300 may begin at step 302 where the method 300 (for example, the communication module 202) may receive data for a space. The space may include one or more floor portions (for example, the floors in the rooms of a building) and one or more ceiling portions (for example, the ceilings in the rooms of the building). The data may include images of the space, such as images captured by a camera, or depth data for the space, such as depth data captured by a LiDAR sensor, or depth data derived from images using photogrammetry or other techniques. The depth data may be in the form of one or more point clouds or a single unified point cloud generated from multiple point clouds that have been aligned.

At step 304 the attribute determination system 102 (for example, the geometry module 204) may generate, based on the data, one or more geometries for the space, such as one or more 3D meshes. For example, if the data includes one or more point clouds, the attribute determination system 102 may align the point clouds to generate a single unified point cloud for the space. The attribute determination system 102 may then generate a 3D mesh using the single unified point cloud. As another example, the attribute determination system 102 may generate a 3D mesh from a single unified point cloud that has been already generated from aligned point clouds. Images, colors, or materials may be projected onto or overlaid onto the 3D mesh to generate a textured 3D mesh. The 3D mesh may include walls, floors, and ceilings of the space, as well as all of the separate objects within the space at the time the underlying data was captured (for example, furniture, furnishings, and the like). In some embodiments, the attribute determination system 102 does not generate one or more geometries for the space but instead receives or accesses one or more geometries that have already been generated for the space, such as one or more 3D meshes.

The attribute determination system 102 may utilize the one or more 3D meshes to identify rooms. The attribute determination system 102 may identify or draw a bounding box within or including a room or a portion of the room in the one or more 3D meshes. A bounding box may be a rectangular area that is typically used in computer graphics, image processing, or computer vision to define the boundaries within an image or a scene. The bounding box may be defined by two coordinates: the top-left corner and the bottom-right corner of the rectangle. Bounding boxes may be commonly used for tasks such as object detection, where each detected object in an image is enclosed within a bounding box to specify its location and scale. It will be appreciated that some embodiments do not use bounding boxes or that any portion of a room (in any shape not limited to squares or rectangles) may be used. In some embodiments, the attribute determination system 102 may classify the rooms into one of multiple categories, such as one of twelve categories, and may vary how the ceiling heights or ceiling shapes are determined based on the room category.

At step 306 the attribute determination system 102 (for example, the attribute module 208) may determine, based on the one or more geometries, floor data for the one or more floor portions. The attribute determination system 102 may determine floor data such as floor elevations based on the one or more geometries using the following. In the following, the one or more geometries may be described as being or including one or more 3D meshes, but it will be understood that other types of geometries may be utilized.

In some embodiments, on a regular grid (for example, 0.2 meters (m) by 0.2 m, although any type of regular or irregular spacing may be utilized), the attribute determination system 102 may cast rays from positions that are outside the one or more 3D meshes, such as positions below the one or more 3D meshes. Additionally or alternatively, the attribute determination system 102 may cast rays from positions that are within the one or more 3D meshes, such as from intermediate positions in parts of the one or more 3D meshes corresponding to the room. The attribute determination system 102 may adjust the grid spacing for positions of the rays so as to, for example, manage the compute requirements for large rooms. In some embodiments, points outside the room, or inside a hole or a nested room may be excluded. Rays that do not impact the one or more 3D meshes (for example rays that do not hit a dimensionally accurate portion of the one or more 3D meshes) may be excluded.

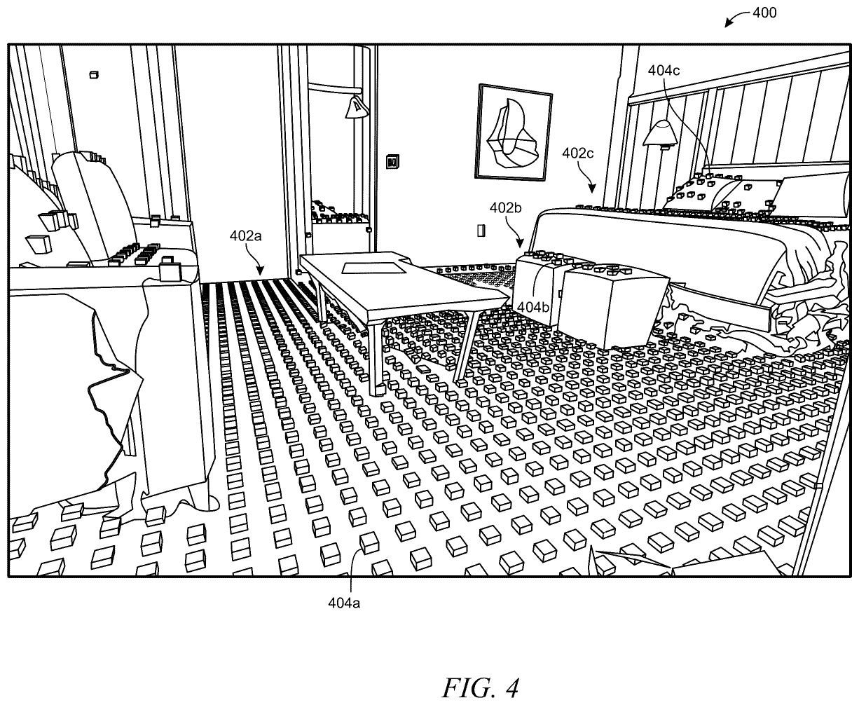

FIG. 4 is a diagram depicting intersections of rays and portions of the one or more 3D meshes according to some embodiments. FIG. 4 depicts a room portion 400 of a 3D mesh for a space that may be a residential home. The room portion 400 includes a floor portion 402a of the 3D mesh. The room portion 400 also includes portions for items proximate to the floor portion 402a, such as an ottoman portion 402b and a bed portion 402c, both of which are proximate to the floor portion 402a. FIG. 4 also depicts intersections of rays cast from positions that are within the 3D mesh or outside the 3D mesh with the room portion 400 of the 3D mesh. The ray-mesh intersections include a ray-mesh intersection 404a for a ray that has impacted the floor portion 402a, a ray-mesh intersection 404b for a ray that has impacted the ottoman portion 402b, and a ray-mesh intersection 404c for a ray that has impacted the bed portion 402c.

In some embodiments, for any number of rays cast up, the attribute determination system 102 may calculate a tilt of the 3D mesh that a ray impacts. The attribute determination system 102 may exclude certain rays if the tilt exceeds a threshold. For example, the attribute determination system 102 may exclude rays impacting the 3D mesh where the tilt is greater than a tilt threshold such as 10 degrees. It will be appreciated that the tilt threshold may be any degree. In some embodiments, a user may set the tilt threshold to any degree value.

In some embodiments, the attribute determination system 102 may terminate the process of casting rays and evaluating height within the one or more 3D meshes and return an unknown ceiling height if a number of per-grid-point ceiling heights is less than a particular threshold (for example, if the rays did not generate enough data). For example, the process of casting rays may terminate if a per-grid-point ceiling heights is less than a particular threshold such as 10 (which corresponds to 0.4 m2 using a 0.2 m grid distance). It will be appreciated that the particular threshold may be any threshold. In some embodiments, a user may set the particular threshold to any value.

The attribute determination system 102 may weight floor elevation values according to how level the surface is at the point of measurement. In one example, this weighting goes from one (1) to zero (0), where one (1) is for level, and zero (0) at the tilt threshold (for example, 10 degrees as discussed herein in an example). It will be appreciated that the weights may have any values. A user may set the weights. Weighting may assist in reducing the effect of floor elevation values for certain ray-mesh intersections, such as the ray-mesh intersection 404c.

In some embodiments, the attribute determination system 102 may create a histogram (or any graph) from weighted per-grid-point floor elevations. A bin may be set to any size. In one example, the bin size is 0.01 m. The attribute determination system 102 may filter histogram bins with an average filter (for example, an average filter over three (3) bins). Filtering may correct certain situations. In one example, filtering corrects situations of the type: bin 1.00 m has 15 samples, bin 2.40 m has 10 samples, and bin 2.41 m has 10 samples. Without filtering, 1.00 m would be the final elevation. It will be appreciated that any ordered process or comparison may be used and any weights applied. In this example, an averaging is applied, however it will be appreciated that any analytical approach or other type of averaging may be used.

In some embodiments, the attribute determination system 102 selects the size of the largest bin in the filtered histogram as a proposed floor elevation. In some embodiments, the attribute determination system 102 utilizes the following algorithm to determine a floor elevation, after identifying the size of the largest bin in the filtered histogram as the proposed floor elevation. First, the attribute determination system 102 may set a variable x to the number (weighted by tilt as above) of per-grid-point floor elevations that are within a particular distance of the proposed elevation. In some embodiments, the particular distance is 0.05 m. Second, the attribute determination system 102 may set a variable x_boosted to the value of x plus a boost parameter. This may make it easier for tiny rooms to pass the following test. In some embodiments, the boost parameter is equal to 0.5 m2. Third, the attribute determination system 102 may determine if the value of x_boosted divided by an area of the room is greater than a particular value. In some embodiments, the particular value is equal to 0.20. If so, the attribute determination system 102 may then accept the proposed floor elevation as the floor elevation. Otherwise, the attribute determination system 102 may return unknown for the floor elevation.

Returning to FIG. 3, also at step 306 the attribute determination system 102 (for example, the attribute module 208) may determine, based on the one or more geometries, ceiling data for the one or more ceiling portions. The attribute determination system 102 may determine ceiling data such as ceiling elevations based on the one or more geometries using the following. In the following, the one or more geometries may be described as being or including one or more 3D meshes, but it will be understood that other types of geometries may be utilized.

In some embodiments, on a regular grid (for example, 0.2 meters (m) by 0.2 m, although any type of regular or irregular spacing may be utilized), the attribute determination system 102 may cast rays from positions that are outside the one or more 3D meshes, such as positions above the one or more 3D meshes. Additionally or alternatively, the attribute determination system 102 may cast rays from positions that are within the one or more 3D meshes, such as from intermediate positions in parts of the one or more 3D meshes corresponding to the room. The attribute determination system 102 may adjust the grid spacing for positions of the rays so as to, for example, manage the compute requirements for large rooms. In some embodiments, points outside the room, or inside a hole or a nested room may be excluded. Rays that do not impact the one or more 3D meshes (for example rays that do not hit a dimensionally accurate portion of the one or more 3D meshes) may be excluded.

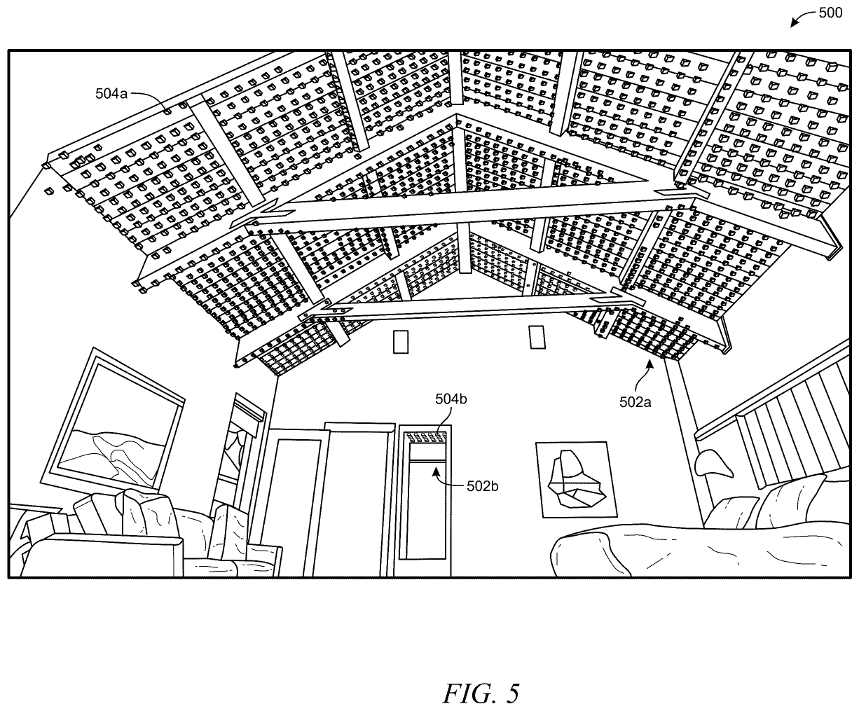

FIG. 5 is a diagram depicting intersections of rays and ceiling portions of the one or more 3D meshes according to some embodiments. FIG. 5 depicts a room portion 500 of a 3D mesh for a space such as a home. The room portion 500 includes a first ceiling portion 502a and a second ceiling portion 502b. FIG. 5 also depicts intersections of rays cast from positions that are within the 3D mesh or outside the 3D mesh with the first ceiling portion 502a and the second ceiling portion 502b of the 3D mesh. The ray-mesh intersections include a ray-mesh intersection 504a for a ray that has impacted the first ceiling portion 502a and a ray-mesh intersection 504b for a ray that has impacted the second ceiling portion 502b.

In some embodiments, for any number of rays cast down, the attribute determination system 102 may calculate the tilt and yaw of the 3D mesh that a ray impacts. The attribute determination system 102 may construct a 2D histogram or ray-mesh intersections with the axes corresponding to tilt and yaw of the mesh at each intersection. For example, the attribute determination system 102 may utilize 72 bins for tilt in the range [0, π/2], and 72 bins for yaw in the range [0, 2π]. The attribute determination system 102 may treat yaw as meaningless when tilt is equal to zero (0), so the attribute determination system 102 may sum all yaw bins for tilt=zero (0) and assign to the bin for yaw=zero (0) and tilt=zero (0). It will be appreciated that the attribute determination system 102 may add or group all or some yaw values in any manner.

The attribute determination system 102 may filter the 2D histogram. For example, the attribute determination system 102 may filter the 2D histogram by applying an approximate Gaussian filter. The attribute determination system 102 may filter the 2D histogram by applying a three (3) by three (3) filter with coefficients {{1, 1, 1}, {1, 2, 1}, {1, 1, 1}}. It will be appreciated that any suitable size filter with any suitable coefficients may be utilized. The attribute determination system 102 may select a yaw and a tilt based on the filter bin(s). For example, the attribute determination system 102 may select a yaw and a tilt of the largest bin. The attribute determination system 102 may erase bins in a five (5) by five (5) neighborhood (or a neighborhood of any size) of the largest bin. If the bin value is below a fixed threshold then the attribute determination system 102 may terminate the process. In some embodiments, if tilt is equal to zero (0), then the attribute determination system 102 may determine ceiling elevation generally the same way that the attribute determination system 102 determines floor elevation.

If the tilt is greater than zero (0), the attribute determination system 102 may proceed as follows. Each local maxima in the histogram may represent a potential ceiling plane. To determine ceiling height for a local maxima in the histogram, the attribute determination system 102 may select all ray-mesh intersections that have yaw and tilt close to yaw and tilt from the histogram. The attribute determination system 102 may utilize RANSAC (random sample consensus) to fit a plane to these points. The attribute determination system 102 may reject the plane if RANSAC is unable to find a plane with sufficient inlier count. The attribute determination system 102 may return tilt and yaw of the plane as the final ceiling tilt and yaw. The attribute determination system 102 may return one or more inlier (from RANSAC) points with the lowest elevation minus the floor elevation as a minimum ceiling height. The attribute determination system 102 may return one or more inlier (from RANSAC) points with the highest elevation minus the floor elevation as a maximum ceiling height. For each ceiling plane the attribute determination system 102 may report tilt and yaw together with the minimum and maximum ceiling height.

For ceilings that are not flat, the minimum and maximum height measurements should not be outliers. For a ceiling with one or more sloped surfaces, the maximum may reflect the maximum height above the room floor. The maximum height for a room may be found away from any of the walls. Conversely, it may not be possible to establish maximum height from the wall segments alone. The height of a flat ceiling may be fixed. In the case of a flat ceiling, this height may also be the minimum and the maximum height.

FIG. 6 is another diagram depicting intersections of rays and ceiling portions of the one or more 3D meshes according to some embodiments. FIG. 6 depicts a room portion 600 of a 3D mesh for a space such as a home. The room portion 600 includes a ceiling portion 602. FIG. 6 also depicts intersections of rays from positions that are within the 3D mesh or outside the 3D mesh with the ceiling portion 602 of the 3D mesh. The ray-mesh intersections include a ray-mesh intersection 604a, a ray-mesh intersection 604b, and a ray-mesh intersection 604c. The ray-mesh intersections 604a-c are inliers when the attribute determination system 102 is finding a ceiling plane.

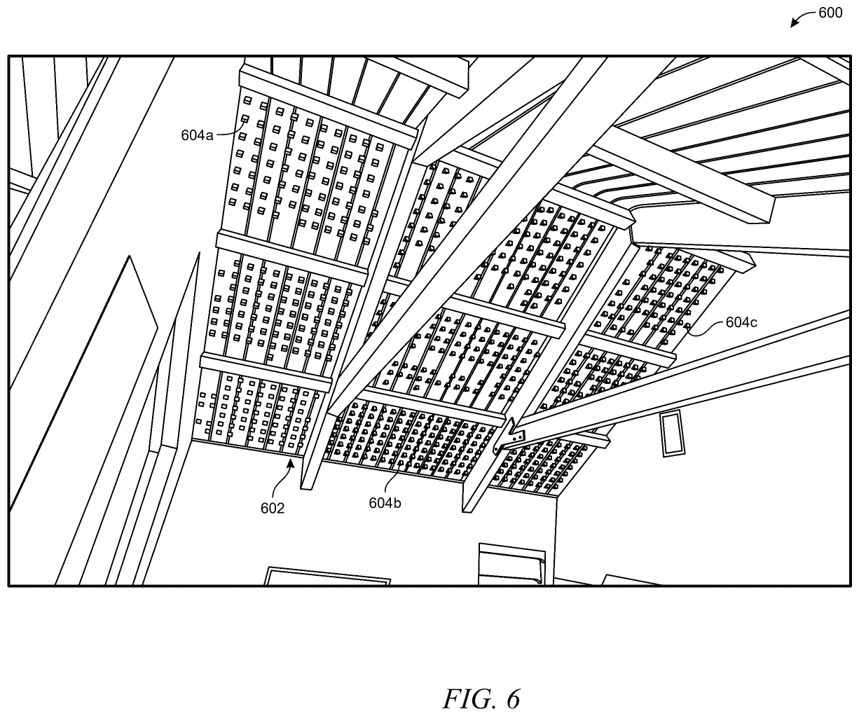

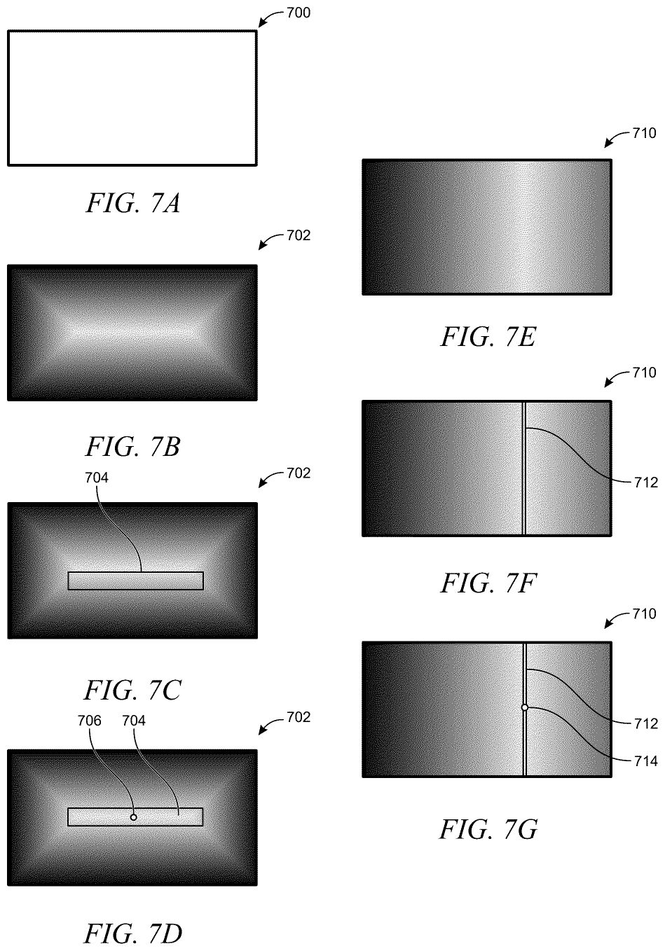

In addition to the minimum or maximum heights, the attribute determination system 102 may return a 2D location where the minimum or maximum heights may be displayed on a floor plan, such as a 2D floor plan or a 3D floor plan. In some embodiments, the attribute determination system 102 may continue according to the following. First, the attribute determination system 102 may find a central position for the ceiling of the room as follows. FIG. 7A depicts an example rectangular room 700. The attribute determination system 102 may determine the 2D distance transform for the room on the 2D floor plan. FIG. 7B depicts an example distance transform 702 of the rectangular room 700. For a rectangular room, the distance transform may have the highest distance along a line parallel to the rectangle's longest sides. The attribute determination system 102 may collect the points that have a distance>0.9 * maximum distance (or any threshold). FIG. 7C depicts the distance transform 702 with a rectangle 704 that includes such points. Of these points the attribute determination system 102 may select the geometric median point as a central location. FIG. 7D depicts the distance transform 702 with a point 706 inside the rectangle 704 that is the geometric median. The attribute determination system 102 may return the point from RANSAC's inlier set that is closest to the central location and with a height within two (2) % of the minimum height or the maximum height. The attribute determination system 102 may utilize suitable percentages other than two (2) %. The attribute determination system 102 may determine additional ceiling planes in the same or different areas of the physical environment by repeating this process. FIG. 7E depicts a distance transform 710 for a room with two ceiling planes and maximum heights in a line that is off-center. FIG. 7F depicts the distance transform 710 with a line 712 that marks the points that are within 2% of the maximum height. FIG. 7G depicts a point 714 that indicates where the maximum height may be displayed on a 2D floor plan or on a 3D floor plan.

Returning to FIG. 3, at step 308 the attribute determination system 102 (for example, the attribute module 208) may determine, based on the floor data and the ceiling data, one or more ceiling heights and one or more shapes for the one or more ceiling portion. The attribute determination system 102 may utilize the processes described herein to determine the ceiling heights. In some embodiments, the attribute determination system 102 may provide an enumerated ceiling shape, which may be flat, sloped, vaulted, or other. The attribute determination system 102 may determine a ceiling shape of flat for certain spaces, such as legacy spaces. The attribute determination system 102 may determine a ceiling shape of sloped for a ceiling that is planar but not flat. The minimum height and maximum height values may reflect the minimum height. The attribute determination system 102 may determine a ceiling shape of vaulted for a ceiling with more than one sloped plane. The attribute determination system 102 may determine a ceiling shape of other as a catch-all for ceilings that do not match a preceding shape type (for example, dome). In some embodiments, the attribute determination system 102 categorizes ceilings as only one of flat and not flat.

At step 310 the attribute determination system 102 (for example, the communication module 202) may provide the one or more ceiling heights and the one or more shapes for display. At step 312 a presentation component 108 of a user system 106 may display one or more 3D representations of the space and the one or more ceiling heights.

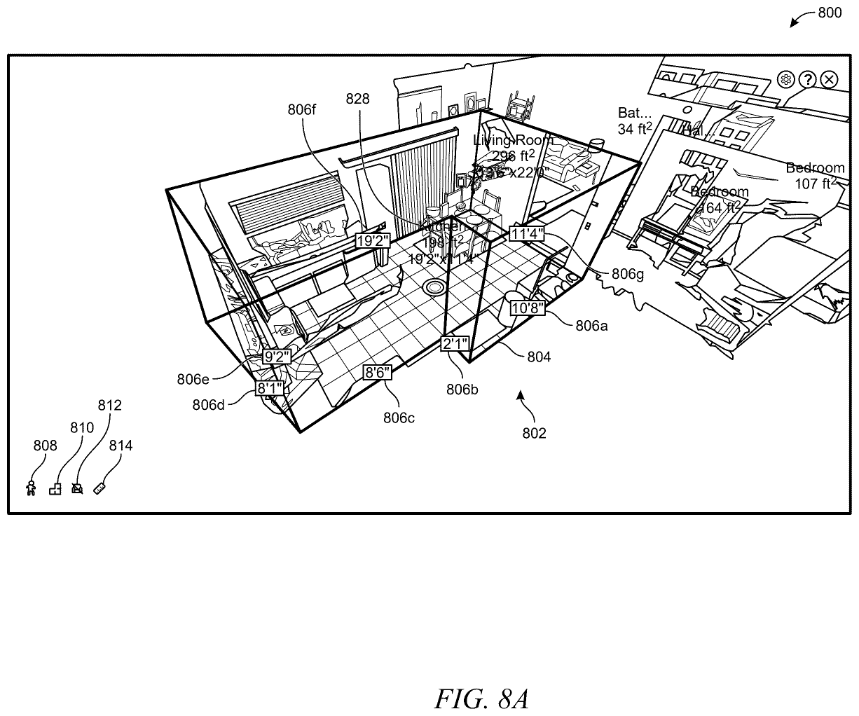

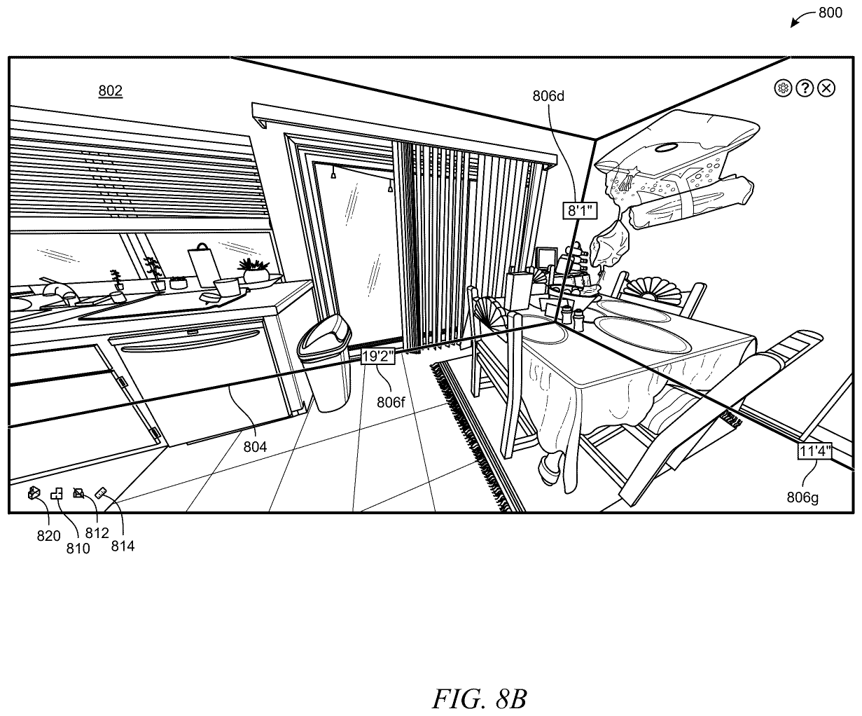

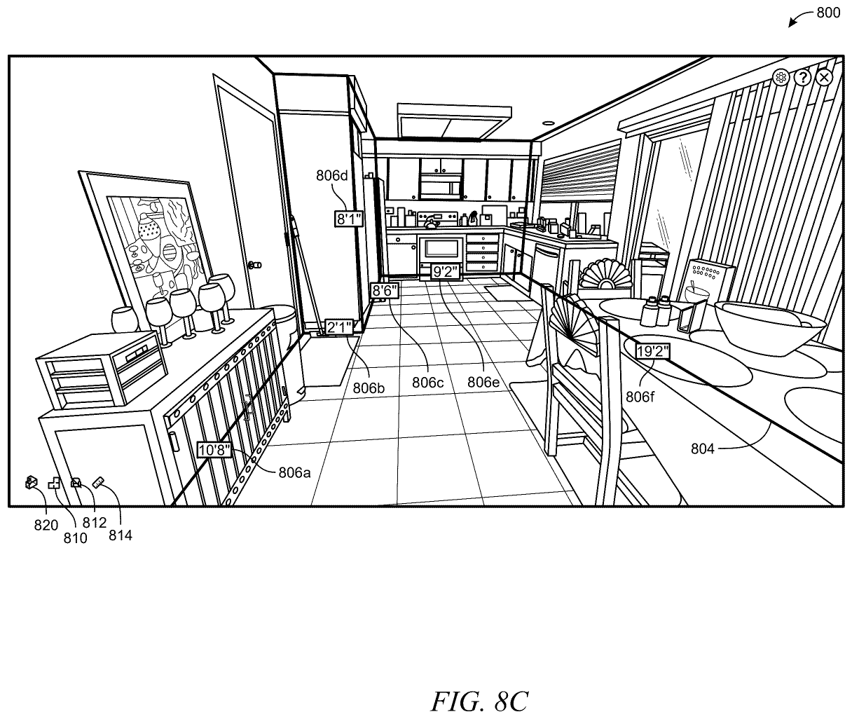

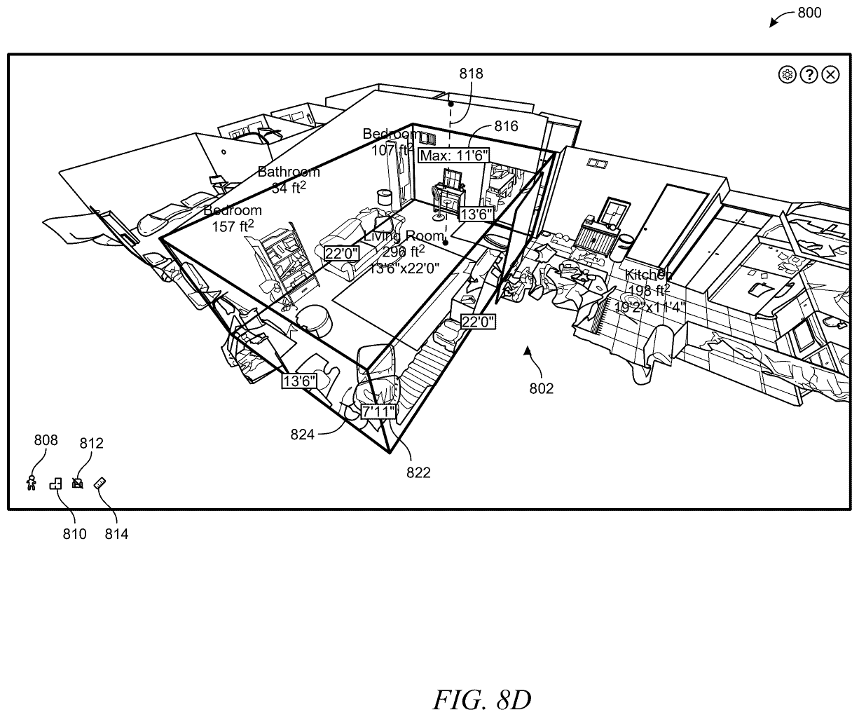

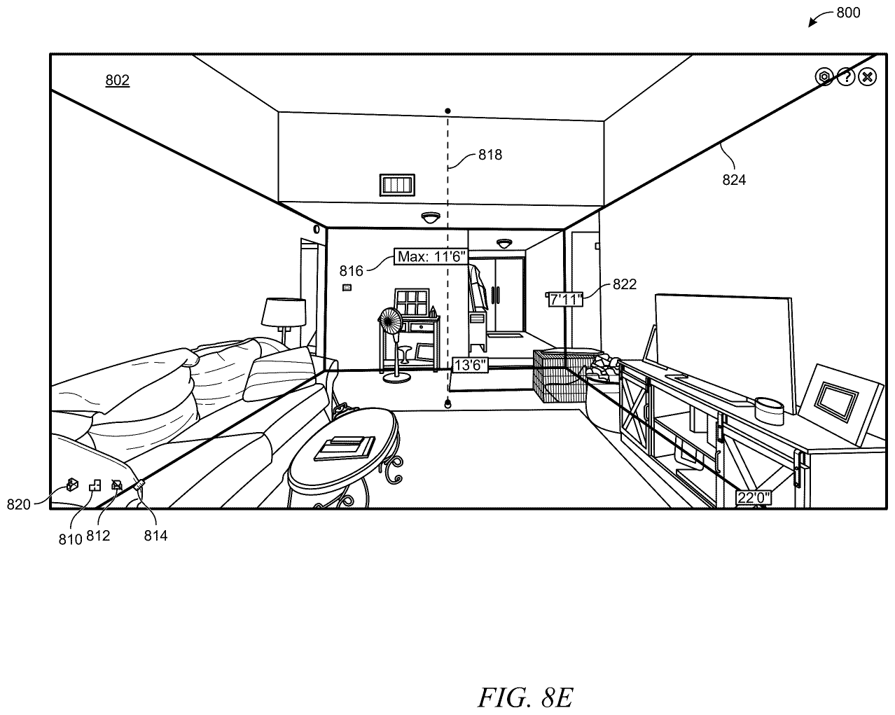

FIGS. 8A to 8E depict a user interface 800 displaying a 3D representation 802 of a space according to some embodiments. The presentation component 108 may display the user interface 800 or the 3D representation 802. The user interface 800 displays a dollhouse view of the 3D representation 802 in FIG. 8A. The user interface 800 includes an icon 808 that may be selected by a user to explore the 3D representation 802, an icon 810 that may be selected by the user to view a top-down orthogonal 2D floor plan for the 3D representation 802, an icon 812 that may be selected by the user to defurnish or furnish the 3D representation 802, and an icon 814 that may be selected by the user to toggle display of a 2D floor plan or a 3D floor plan for the 3D representation 802. A portion 804 of a 3D floor plan is displayed for a portion of the 3D representation 802, which is a kitchen, as indicated by a room label 828. In some embodiments, the user interface 800 displays the portion 804 of the 3D floor plan in response to a selection of a region of the 3D representation 802 by a user, such as a room. In some embodiments, the user interface 800 displays the entire 3D floor plan. The portion 804 of the 3D floor plan is displayed as a 3D wireframe overlaid on the portion of the 3D representation 802. The portion 804 includes multiple measurements 806 for the portion of the 3D representation 802 (shown individually as measurement 806a, measurement 806b, measurement 806c, measurement 806d, measurement 806e, measurement 806f, and measurement 806g). The multiple measurements 806 include a measurement 806d for the ceiling height of the kitchen.

In some embodiments, there may be a minimum height threshold for showing the ceiling height. In such embodiments, the user interface 800 may display a 2D floor plan instead of a 3D floor plan if the ceiling height does not meet or exceed the minimum height threshold.

FIGS. 8B and 8C depicts the user interface 800 after the user has selected the icon 808 to explore the 3D representation 802. In the user interface 800, an icon 820 that the user may select to return to the dollhouse view has replaced the icon 808. The portion 804 of the 3D floor plan is displayed as a 3D wireframe overlaid on a portion of the 3D representation 802. The user interface 800 may display the portion 804 in various ways, such as displaying the portion 804 such that the portion 804 is always visible, even when the portion 804 should be obscured by furniture or other items in the 3D representation 802. Alternatively, the user interface 800 may display furniture or other items as obscuring the portion 804. The user interface 800 also displays the measurement 806d for the ceiling height of the kitchen.

FIG. 8D depicts the user interface 800 after the user has selected the icon 820 to return to the dollhouse view. FIG. 8D also depicts that the view of the 3D representation 802 has changed to another portion of the 3D representation 802. Accordingly, the user interface 800 displays another portion 824 of the 3D floor plan for the other portion of the 3D representation, which is a living room. The user interface 800 displays a label 816 that indicates the maximum ceiling height in the living room and a dashed line 818 that indicates a position or location where the maximum ceiling height has been determined to be located. The user interface 800 also displays a measurement 822 for another (non-maximum) ceiling height of the living room.

FIG. 8E depicts the user interface 800 after the user has selected the icon 808 to explore the 3D representation 802. The portion 824 of the 3D floor plan is displayed as a 3D wireframe overlaid on a portion of the 3D representation 802. The user interface 800 displays the label 816 that indicates the maximum ceiling height in the living room and the dashed line 818 that indicates the position or location where the maximum ceiling height has been determined to be located. In some embodiments, the user interface 800 only displays the label 816 and the dashed line 818 for non-flat ceilings. In some embodiments, the user interface 800 displays the label 816 and the dashed line 818 for flat ceilings. The user interface 800 also displays the measurement 822 for the other (non-maximum) ceiling height of the living room.

Although portions of the 3D floor plan may be described as displayed as a 3D wireframe, portions of which are overlaid on portions of the 3D representation 802, it is to be understood that a 3D floor plan and associated data may be displayed without displaying another 3D representation such as the 3D representation 802. The presentation component 108 may display the 3D floor plan, including measurements, floor areas, room labels, or ceiling heights, without overlaying the 3D floor plan on other 3D representations such as the 3D representation 802. The 3D floor plan may be considered as a 3D representation. Accordingly, providing or displaying one or more 3D representations may include providing or displaying one or more 3D floor plans.

According to various embodiments, the user interface 800 depicted in FIGS. 8A to 8E may allow for a user to search for information regarding the view or the physical environment to be searched. In some embodiments, ceiling shape attributes or ceiling heights may be available as searchable attributes for rooms or areas of spaces. It will be appreciated that information may be searched over a variety of properties or 3D representations. For example, searchable ceiling types may allow for searches for properties that have living rooms with a vaulted ceiling (or any kind of ceiling type). As another example, searchable ceiling heights may allow for searches for properties that have foyers above a certain height (for example, above 12 feet). As another example, searchable ceiling heights may allow for searches for properties that have rooms with 10 foot ceilings. In some embodiments, the user interface 800 may allow for display of ceiling height (for example, median, maximum, minimum, or the like).

The 3D representation system 104 report may report median ceiling height as the primary room height for a room or other area of a space. In some embodiments, the report may include the minimum or maximum values for all or part of a ceiling. In some embodiments, different information may be provided based on ceiling type (for example, a median ceiling height may be provided when the ceiling is flat and when the ceiling is another type, the minimum or maximum values may be provided for all or part of the ceiling). In some embodiments, a particular height measurement (e.g., median) may be used when a particular percentage of the ceiling (e.g., 50%) is at a particular height and otherwise the minimum or maximum values are provided). It will be appreciated that any analytical approach may be used and/or further criteria defined and applied to eliminate outliers. If there is a maximum ceiling height that is significantly different than the median, the maximum ceiling height may be shown parenthetically after the median ceiling height. In some embodiments, if a ceiling has a shape attribute that is not “other,” the shape icon may be provide nearby the ceiling height measurement.

In some embodiments, the 3D representation system 104 may allow users to edit or otherwise customize 3D representations. One example of a component that may allow users to edit 3D representations is Matterport Workshop. After a user has edited or customized a 3D representation, the 3D representation system 104 may generate updated ceiling heights based on user inputs to modify the 3D representation. The 3D representation system 104 may also generate updated ceiling shapes for rooms in response to user edits. In some embodiments, a user may be able to select a ceiling shape from among an enumerated list of ceiling shapes (for example, flat, sloped, vaulted, or other). In some embodiments, a user may provide names of different types of ceilings or provide criteria for each different ceiling type (for example, through a graphical user interface (GUI)). In some embodiments, the 3D representation system 104 may receive the criteria or classifications from a user and then make measurements or classifications using some embodiments described herein. The 3D representation system 104 may provide the user the ceiling types of the 3D model as well as all or some measurements that apply to each ceiling classified. The user may make adjustments to the classification (for example, change the classifications) for one or more different ceilings, change criteria, change classifications, or the like.

Returning to FIG. 3, at step 314, the 3D representation system 104 may receive one or more inputs to modify the one or more 3D representations. At step 316 the 3D representation system 104 may update, based on the one or more inputs, the one or more ceiling heights to generate one or more updated ceiling heights. At step 318 a presentation component 108 of a user system 106 may display the one or more 3D representations and the one or more updated ceiling heights. At step 320 the 3D representation system 104 may generate a floor plan for the space that includes the one or more ceiling heights, such as a 2D floor plan or a 3D floor plan. At step 322 the 3D representation system 104 may provide the floor plan for display. The presentation component 108 may display the floor plan, as depicted in FIGS. 8A to 8E, which show a 3D floor plan.

In some embodiments, the attribute determination system 102 (or another system, such as the 3D representation system 104) may determine a volume of a room or area of a space and provide the volume. The volume may be determined for a portion of a room, a room, a floor, an entire building, or the like. In some embodiments, volume may be utilized as a proxy for mean ceiling height that can also be used for HVAC calculations. In some embodiments, HVAC model or specifications may be received (for example, received from an owner, utility, metadata file, or the like). If the HVAC model or type is received, more detailed information regarding HVAC specifications may be retrieved or requested (for example, from a third party website). In some embodiments, the attribute determination system 102 may assess the capabilities of the HVAC specifications in view of one or more volumes of a space. The attribute determination system 102 may provide information whether the HVAC is capable or incapable of adequately cooling or heating a space. In some embodiments, the attribute determination system 102 may provide information if HVAC performance or capability is not clear.

In various embodiments the attribute determination system 102 or another system (for example, the 3D representation system 104) may make livable area measurements based on measurements of the 3D model or metadata associated with the physical space. In one example, livable area measurements in areas of a room with low ceilings may be discounted from livable area (for example, by comparing or analyzing applicable regulations, laws, or rules). Various jurisdictions may have requirements related to ceiling height that a room or an area in a residential home must meet in order to be considered livable area under the requirements. The attribute determination system 102 or another system (for example, the 3D representation system 104) may utilize the ceiling height to determine if the room or the area meets the requirements to be considered livable area. Other uses will be apparent.

As described herein, certain embodiments of the attribute determination system 102 utilize one or more 3D meshes and casting rays to determine floor elevations, ceiling elevations, or ceiling shapes. Examples of types of geometries that could be used by other embodiments of the attribute determination system 102 are 3D point clouds or other 3D clouds such as Gaussian splats, volumetric representations such as signed distance field (SDF) volumes, neural representations such as neural radiance fields (NeRFs), or other surface or solid 3D representations such as control-point-based or other parametric or implicit surfaces, constructive solid geometry, etc. One example approach for determining floor elevations, ceiling elevations, or ceiling shapes in other embodiments include detecting and fitting planes or other shapes in the one or more geometries. The attribute determination system 102 may then determine that such planes or shapes are ceiling or floor surfaces. As another example, the attribute determination system 102 may analyze histograms or other graphs of the elevations of points or other elements of the geometry to determine floor elevations, ceiling elevations, or ceiling shapes. In another example approach, the attribute determination system 102 may utilize a neural network such as one involving PointNet to infer either direct results, such as ceiling heights, or intermediate results, such as which portions of the geometry belong to ceilings and floors, simplified geometric representations, or other data. The attribute determination system 102 may then utilize the direct results or the intermediate results to determine floor elevations, ceiling elevations, or ceiling shapes. Other approaches will be apparent.

FIG. 9 depicts a block diagram of an example digital device 900 according to some embodiments. The digital device 900 is shown in the form of a general-purpose computing device. The digital device 900 includes at least one processor 902, which may be or include one or more central processing units (CPUs) or one or more graphics processing units (GPUs), random access memory (RAM 904), communication interface 906, input/output device 908, storage 910, and a system bus 912 that couples various system components including storage 910 to the at least one processor 902. A set (which may be a physical set or a logical set) of one or more of the digital device 900 may be referred to as a computing system.

System bus 912 represents one or more of any of several types of bus structures, including a memory bus or memory controller, a peripheral bus, an accelerated graphics port, and a processor or local bus using any of a variety of bus architectures. By way of example, and not limitation, such architectures include Industry Standard Architecture (ISA) bus, Micro Channel Architecture (MCA) bus, Enhanced ISA (EISA) bus, Video Electronics Standards Association (VESA) local bus, and Peripheral Component Interconnect (PCI) bus.

The digital device 900 typically includes a variety of computer system readable media, such as computer system readable storage media. Such media may be any available media that is accessible by any of the systems described herein and it includes both volatile and nonvolatile media, removable and non-removable media.

In some embodiments, the at least one processor 902 is configured to execute executable instructions (for example, programs). In some embodiments, the at least one processor 902 comprises circuitry or any processor capable of processing the executable instructions.

In some embodiments, RAM 904 stores programs or data. In various embodiments, working data is stored within RAM 904. The data within RAM 904 may be cleared or ultimately transferred to storage 910, such as prior to reset or powering down the digital device 900.

In some embodiments, the digital device 900 is coupled to a network via communication interface 906. The digital device 900 can communicate with one or more networks such as a local area network (LAN), a general wide area network (WAN), or a public network (for example, the Internet).

In some embodiments, input/output device 908 is any device that inputs data (for example, mouse, keyboard, stylus, sensors, etc.) or outputs data (for example, speaker, display, virtual reality headset).

In some embodiments, storage 910 can include computer system readable media in the form of non-volatile memory, such as read only memory (ROM), programmable read only memory (PROM), solid-state drives (SSD), flash memory, or cache memory. Storage 910 may further include other removable/non-removable, volatile/non-volatile computer system storage media. By way of example only, storage 910 can be provided for reading from and writing to a non-removable, non-volatile magnetic media. The storage 910 may include a non-transitory computer-readable medium, or multiple non-transitory computer-readable media, which stores programs or applications for performing functions such as those described herein. Although not shown, a magnetic disk drive for reading from and writing to a removable, non-volatile magnetic disk (for example, a “floppy disk”), and an optical disk drive for reading from or writing to a removable, non-volatile optical disk such as a CDROM, DVD-ROM or other optical media can be provided. In such instances, each can be connected to system bus 912 by one or more data media interfaces. As will be further depicted and described below, storage 910 may include at least one program product having a set (for example, at least one) of program modules that are configured to carry out the functions of embodiments of the technology. In some embodiments, RAM 904 is found within storage 910.

Programs/utilities, having a set (at least one) of program modules may be stored in storage 910 by way of example, and not limitation, as well as an operating system, one or more application programs, other program modules, and program data. Each of the operating system, one or more application programs, other program modules, and program data or some combination thereof, may include an implementation of a networking environment. Program modules generally carry out the functions or methodologies of embodiments of the technology as described herein.

It should be understood that although not shown, other hardware or software components could be used in conjunction with the digital device 900. Examples include, but are not limited to microcode, device drivers, redundant processing units, and external disk drive arrays, RAID systems, tape drives, and data archival storage systems, etc.

Exemplary embodiments are described herein in detail with reference to the accompanying drawings. However, the present disclosure can be implemented in various manners, and thus should not be construed to be limited to the embodiments disclosed herein. On the contrary, those embodiments are provided for the thorough and complete understanding of the present disclosure, and completely conveying the scope of the present disclosure.

It will be appreciated that aspects of one or more embodiments may be embodied as a system, method, or computer program product. Accordingly, aspects may take the form of an entirely hardware embodiment, an entirely software embodiment (including firmware, resident software, micro-code, etc.) or an embodiment combining software and hardware aspects that may all generally be referred to herein as a circuit, module or system. Furthermore, aspects may take the form of a computer program product embodied in one or more computer readable medium(s) having computer readable program code embodied thereon.

Any combination of one or more computer readable medium(s) may be utilized. The computer readable medium may be a computer readable signal medium or a computer readable storage medium. A computer readable storage medium may be, for example, but not limited to, an electronic, magnetic, optical, electromagnetic, infrared, or semiconductor system, apparatus, or device, or any suitable combination of the foregoing. More specific examples (a non-exhaustive list) of the computer readable storage medium would include the following: an electrical connection having one or more wires, a portable computer diskette, a hard disk, a random access memory (RAM), a read-only memory (ROM), an erasable programmable read-only memory (EPROM or Flash memory), a solid state drive (SSD), an optical fiber, a portable compact disc read-only memory (CD-ROM), an optical storage device, a magnetic storage device, or any suitable combination of the foregoing. In the context of this document, a computer readable storage medium may be any tangible medium that can contain or store a program or data for use by or in connection with an instruction execution system, apparatus, or device.

A transitory computer readable signal medium may include a propagated data signal with computer readable program code embodied therein, for example, in baseband or as part of a carrier wave. Such a propagated signal may take any of a variety of forms, including, but not limited to, electro-magnetic, optical, or any suitable combination thereof.

Program code embodied on a computer readable medium may be transmitted using any appropriate medium, including but not limited to wireless, wireline, optical fiber cable, RF, etc., or any suitable combination of the foregoing.

Computer program code for carrying out operations for aspects of the present technology may be written in any combination of one or more programming languages, including an object-oriented programming language such as Java, Smalltalk, C++, Python, or the like and conventional procedural programming languages, such as the C programming language or similar programming languages. The computer program code may execute entirely on any of the systems described herein or on any combination of the systems described herein.

Aspects of the present technology may be described with reference to flowchart illustrations or block diagrams of methods, apparatus (systems) and computer program products according to embodiments of the technology. It will be understood that each block of the flowchart illustrations or block diagrams, and combinations of blocks in the flowchart illustrations or block diagrams, can be implemented by computer program instructions. These computer program instructions may be provided to a processor of a general-purpose computer, special purpose computer, or other programmable data processing apparatus to produce a machine, such that the instructions, which execute via the processor of the computer or other programmable data processing apparatus, create means for implementing the functions/acts specified in the flowchart or block diagram block or blocks.

These computer program instructions may also be stored in a computer readable medium that can direct a computer, other programmable data processing apparatus, or other devices to function in a particular manner, such that the instructions stored in the computer readable medium produce an article of manufacture including instructions which implement the function/act specified in the flowchart or block diagram block or blocks.

The computer program instructions may also be loaded onto a computer, other programmable data processing apparatus, or other devices to cause a series of operational steps to be performed on the computer, other programmable apparatus or other devices to produce a computer implemented process such that the instructions which execute on the computer or other programmable apparatus provide processes for implementing the functions/acts specified in the flowchart or block diagram block or blocks.

While particular elements, embodiments and applications have been shown and described, it will be understood, of course, that the claims are not limited thereto since modifications may be made by those skilled in the art without departing from the spirit and scope of the present disclosure, particularly in light of the foregoing teachings. Such modifications are to be considered within the purview and scope of the claims appended hereto.

While specific examples are described above for illustrative purposes, various equivalent modifications are possible. For example, while processes or blocks are presented in a given order, alternative implementations may perform routines having steps, or employ systems having blocks, in a different order, and some processes or blocks may be deleted, moved, added, subdivided, combined, or modified to provide alternative or sub-combinations. Each of these processes or blocks may be implemented in a variety of different ways. Also, while processes or blocks are at times shown as being performed in series, these processes or blocks may instead be performed or implemented concurrently or in parallel or may be performed at different times. Further any specific numbers noted herein are only examples: alternative implementations may employ differing values or ranges.

Throughout this specification, plural instances may implement components, operations, or structures described as a single instance. Structures and functionality presented as separate components in example configurations may be implemented as a combined structure or component. Similarly, structures and functionality presented as a single component may be implemented as separate components. These and other variations, modifications, additions, and improvements fall within the scope of the subject matter herein. Furthermore, any specific numbers noted herein are only examples: alternative implementations may employ differing values or ranges.

Components may be described or illustrated as contained within or connected with other components. Such descriptions or illustrations are only examples, and other configurations may achieve the same or similar functionality. Components may be described or illustrated as “coupled,” “couplable,” “operably coupled,” “communicably coupled” and the like to other components. Such description or illustration should be understood as indicating that such components may cooperate or interact with each other, and may be in direct or indirect physical, electrical, or communicative contact with each other.

Components may be described or illustrated as “configured to,” “adapted to,” “operative to,” “configurable to,” “adaptable to,” “operable to” and the like. Such description or illustration should be understood to encompass components both in an active state and in an inactive or standby state unless required otherwise by context.

The use of “or” in this disclosure is not intended to be understood as an exclusive “or.” Rather, “or” is to be understood as including “and/or.” For example, the phrase “providing products or services” is intended to be understood as having several meanings: “providing products,” “providing services,” and “providing products and services.” Headings in this application may be provided for organization and may not necessarily be used to interpret or constrain the purview and scope of the claims appended hereto. Moreover, concepts or features of technologies described under a particular heading may be used in technologies described under other headings. Accordingly, technologies described under a particular heading are not limited to the concepts or features described under that particular heading.

It may be apparent that various modifications may be made, and other embodiments may be used without departing from the broader scope of the discussion herein. For example, the techniques described herein may be utilized to determine room widths or lengths of rooms of a space by casting rays that impact portions of one or more 3D meshes corresponding to walls of the rooms of the space. Therefore, these and other variations upon the example embodiments are intended to be covered by the disclosure herein.

1. One or more non-transitory computer-readable media comprising executable instructions, the executable instructions being executable by one or more processors to perform a method, the method comprising:
receiving data for a space, the space including one or more floor portions and one or more ceiling portions, the data including depth data for the space or images of the space;
generating, based on the data, one or more geometries for the space;
determining, based on the one or more geometries, floor data for the one or more floor portions and ceiling data for the one or more ceiling portions;
determining, based on the floor data and the ceiling data, one or more ceiling heights for the one or more ceiling portions; and
providing the one or more ceiling heights for display.

2. The one or more non-transitory computer-readable media of claim 1, the method further comprising:
determining, based on the ceiling data, one or more ceiling shapes for the one or more ceiling portions; and
providing the one or more ceiling shapes for display.

3. The one or more non-transitory computer-readable media of claim 1, the method further comprising:
displaying one or more 3D representations of the space, the one or more 3D representations including the one or more ceiling heights;
receiving one or more inputs to modify the one or more 3D representations;
updating, based on the one or more inputs, the one or more ceiling heights to generate one or more updated ceiling heights; and
displaying the one or more 3D representations, the one or more 3D representations including the one or more updated ceiling heights.

4. The one or more non-transitory computer-readable media of claim 1 wherein the one or more ceiling heights include one or more minimum ceiling heights, one or more maximum ceiling heights, or one or more median ceiling heights.

5. The one or more non-transitory computer-readable media of claim 1, the method further comprising:
generating a floor plan for the space, the floor plan including the one or more ceiling heights; and
providing the floor plan for display.

6. The one or more non-transitory computer-readable media of claim 1 wherein the one or more geometries include one or more 3D meshes, the one or more 3D meshes including one or more first 3D portions representing the one or more floor portions or first items proximate to the one or more floor portions and one or more second 3D portions representing the one or more ceiling portions or second items proximate to the one or more ceiling portions, and wherein determining, based on the one or more geometries, the floor data and the ceiling data includes:
casting rays to impact the one or more first 3D portions;
casting rays to impact the one or more second 3D portions;
determining, based on casting rays, one or more floor elevations and one or more ceiling elevations; and
determining, based on the one or more floor elevations and the one or more ceiling elevations, the floor data and the ceiling data.

7. The one or more non-transitory computer-readable media of claim 6 wherein casting rays to impact the one or more first 3D portions includes casting rays to impact the one or more first 3D portions from first positions that are outside the one or more 3D meshes and casting rays to impact the one or more second 3D portions includes casting rays to impact the one or more second 3D portions from second positions that are outside the one or more 3D meshes.

8. The one or more non-transitory computer-readable media of claim 6 wherein casting rays to impact the one or more first 3D portions includes casting rays to impact the one or more first 3D portions from first positions that are within the one or more 3D meshes and casting rays to impact the one or more second 3D portions includes casting rays to impact the one or more second 3D portions from second positions that are within the one or more 3D meshes.

9. The one or more non-transitory computer-readable media of claim 6 wherein determining, based on casting rays, the one or more floor elevations includes:
determining multiple initial floor elevations;
determining multiple floor tilts;
weighting, based on the multiple floor tilts, the multiple initial floor elevations to generate multiple weighted initial floor elevations; and
determining, based on the multiple weighted initial floor elevations, the one or more floor elevations.

10. The one or more non-transitory computer-readable media of claim 6 wherein determining, based on casting rays, the one or more ceiling elevations includes:
determining multiple initial ceiling elevations;
determining multiple ceiling tilts and multiple ceiling yaws; and
determining, based on the multiple ceiling tilts and the multiple ceiling yaws, the one or more ceiling elevations.

11. The one or more non-transitory computer-readable media of claim 1 wherein the one or more ceiling heights include a maximum ceiling height or a minimum ceiling height, and the method further comprises:
determining a location for the maximum ceiling height or the minimum ceiling height; and
providing the location for display.

12. The one or more non-transitory computer-readable media of claim 11 wherein determining the location for the maximum ceiling height or the minimum ceiling height includes:
determining, based on the one or more geometries, one or more ceiling planes; and
determining, based on the one or more ceiling planes, the location for the maximum ceiling height or the minimum ceiling height.

13. A method comprising:
receiving data for a space, the space including one or more floor portions and one or more ceiling portions, the data including depth data for the space or images of the space;
generating, based on the data, one or more geometries for the space;
determining, based on the one or more geometries, floor data for the one or more floor portions and ceiling data for the one or more ceiling portions;
determining, based on the floor data and the ceiling data, one or more ceiling heights for the one or more ceiling portions; and
providing the one or more ceiling heights for display.

14. The method of claim 13, further comprising:
determining, based on the ceiling data, one or more ceiling shapes for the one or more ceiling portions; and
providing the one or more ceiling shapes for display.

15. The method of claim 13, further comprising:
displaying one or more 3D representations of the space, the one or more 3D representations including the one or more ceiling heights;
receiving one or more inputs to modify the one or more 3D representations;
updating, based on the one or more inputs, the one or more ceiling heights to generate one or more updated ceiling heights; and
displaying the one or more 3D representations, including the one or more updated ceiling heights.

16. The method of claim 13 wherein the one or more ceiling heights include one or more minimum ceiling heights, one or more maximum ceiling heights, or one or more median ceiling heights.

17. The method of claim 13, further comprising:
generating a floor plan for the space, the floor plan including the one or more ceiling heights; and
providing the floor plan for display.

18. The method of claim 13 wherein the one or more geometries include one or more 3D meshes, the one or more 3D meshes including one or more first 3D portions representing the one or more floor portions or first items proximate to the one or more floor portions and one or more second 3D portions representing the one or more ceiling portions or second items proximate to the one or more ceiling portions, and wherein determining, based on the one or more geometries, the floor data and the ceiling data includes:
casting rays to impact the one or more first 3D portions;
casting rays to impact the one or more second 3D portions;
determining, based on casting rays, one or more floor elevations and one or more ceiling elevations; and
determining, based on the one or more floor elevations and the one or more ceiling elevations, the floor data and the ceiling data.

19. The method of claim 18 wherein casting rays to impact the one or more first 3D portions includes casting rays to impact the one or more first 3D portions from first positions that are outside the one or more 3D meshes and casting rays to impact the one or more second 3D portions includes casting rays to impact the one or more second 3D portions from second positions that are outside the one or more 3D meshes.

20. The method of claim 18 wherein casting rays to impact the one or more first 3D portions includes casting rays to impact the one or more first 3D portions from first positions that are within the one or more 3D meshes and casting rays to impact the one or more second 3D portions includes casting rays to impact the one or more second 3D portions from second positions that are within the one or more 3D meshes.

21. The method of claim 18 wherein determining, based on casting rays, the one or more floor elevations includes:
determining multiple initial floor elevations;
determining multiple floor tilts;
weighting, based on the multiple floor tilts, the multiple initial floor elevations to generate multiple weighted initial floor elevations; and
determining, based on the multiple weighted initial floor elevations, the one or more floor elevations.

22. The method of claim 18 wherein determining, based on casting rays, the one or more ceiling elevations includes:
determining multiple initial ceiling elevations;
determining multiple ceiling tilts and multiple ceiling yaws; and
determining, based on the multiple ceiling tilts and the multiple ceiling yaws, the one or more ceiling elevations.

23. The method of claim 13 wherein the one or more ceiling heights include a maximum ceiling height or a minimum ceiling height, and further comprising:
determining a location for the maximum ceiling height or the minimum ceiling height; and
providing the location for display.

24. The method of claim 23 wherein determining the location for the maximum ceiling height or the minimum ceiling height includes:
determining, based on the one or more geometries, one or more ceiling planes; and
determining, based on the one or more ceiling planes, the location for the maximum ceiling height or the minimum ceiling height.

25. A system comprising at least one processor and at least one memory including executable instructions that when executed by the at least one processor cause the system to:
receive data for a space, the space including one or more floor portions and one or more ceiling portions, the data including depth data for the space or images of the space;
generate, based on the data, one or more geometries for the space;
determine, based on the one or more geometries, floor data for the one or more floor portions and ceiling data for the one or more ceiling portions;
determine, based on the floor data and the ceiling data, one or more ceiling heights for the one or more ceiling portions; and
provide the one or more ceiling heights for display.
